(19) United States
(12) Patent Application Publication
(10) Pub. No.: US 2008/0210989 A1
(43) Pub. Date: Sep. 4, 2008

(54) SEMICONDUCTOR DEVICE

(75) Inventor: Kohei NAITO, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Nakakoma-gun (JP)

(21) Appl. No.: 12/020,982

(22) Filed: Jan. 28, 2008

(30) Foreign Application Priority Data
Jan. 26, 2007 (JP) 2007-016129

(51) Int. Cl. H01L 27/095

(52) U.S. Cl. 257/276; 257/E27.068

(57) ABSTRACT

A semiconductor device includes a p-type semiconductor layer made of a compound semiconductor provided on a substrate, a compound semiconductor layer provided on the p-type semiconductor layer, active regions that are provided on the compound semiconductor layer and are adjacent to each other across an isolation region, a connecting portion that is connected to the p-type semiconductor layer in the isolation region located between the active regions or a region adjacent to another region between the active regions, and FETs respectively provided in the active regions adjacent to each other, a source electrode of at least one of the FETs being connected to a potential of the connecting portion in a region other than the active regions.

### BACKGROUND OF THE INVENTION

1. Field of the Invention

The present invention relates to semiconductor devices, and more particularly, to a semiconductor device having a p-type semiconductor layer provided on a substrate, and a connecting portion connected to the p-type semiconductor layer.

2. Description of the Related Art

FETs (Field Effect Transistors) using compound semiconductors are used in MMICs (Microwave Monolithic Integrated Circuits) handling high frequencies and high output powers. In an FET using compound semiconductors, when an electrode close to the FET is set at a negative potential, the drain current of the FET is reduced and the threshold voltage shifts to the positive side. This phenomenon is called a side-gate effect.

Japanese Patent Application Publication No. 2005-72378 proposes a compound semiconductor FET having an arrangement in which a p-type semiconductor layer is provided on a substrate. According to this publication, the drain breakdown can be improved.

However, the proposed arrangement having the p-type semiconductor layer on the substrate increases the side-gate effect.

### SUMMARY OF THE INVENTION

The present invention has been made in view of the above circumstances, and provides a semiconductor device having a reduced side-gate effect.

According to an aspect of the present invention, there is provided a semiconductor device including: a p-type semiconductor layer made of a compound semiconductor provided on a substrate; a compound semiconductor layer provided on the p-type semiconductor layer; active regions that are provided on the compound semiconductor layer and are adjacent to each other across an isolation region; a connecting portion that is connected to the p-type semiconductor layer in the isolation region located between the active regions or a region adjacent to another region between the active regions; and FETs respectively provided in the active regions adjacent to each other, a source electrode of at least one of the FETs being connected to a potential of the connecting portion in a region other than the active regions.

### BRIEF DESCRIPTION OF THE DRAWINGS

FIG. 1 is a schematic cross-sectional view of a semiconductor device in accordance with a first embodiment;

FIG. 2 is a schematic plan view of the semiconductor device in accordance with the first embodiment;

FIG. 3 is a schematic cross-sectional view of a semiconductor device in accordance with a first comparative example;

FIG. 4 is a schematic plan view of the semiconductor devices in accordance with the first and second comparative examples;

FIG. 5 is a schematic cross-sectional view of the semiconductor device in accordance with the second comparative example;

FIG. 6 shows measurement results of the side-gate effect in the first and second comparative examples and a result of simulating the side-gate effect in the first embodiment;

FIG. 7 is a schematic plan view of a semiconductor device in accordance with a first variation of the first embodiment;

FIG. 8 is a schematic plan view of a semiconductor device in accordance with a second embodiment;

FIG. 9 is a schematic plan view of a semiconductor device in accordance with a first variation of the second embodiment;

FIG. 10 is a schematic plan view of a semiconductor device in accordance with a second variation of the second embodiment;

FIG. 11 is a schematic plan view of a semiconductor device in accordance with a third embodiment; and

FIG. 12 is a schematic plan view of a semiconductor device in accordance with a first variation of the third embodiment.

### DESCRIPTION OF THE PREFERRED EMBODIMENTS

A description will now be given of embodiments of the present invention with reference to the accompanying drawings.

### First Embodiment

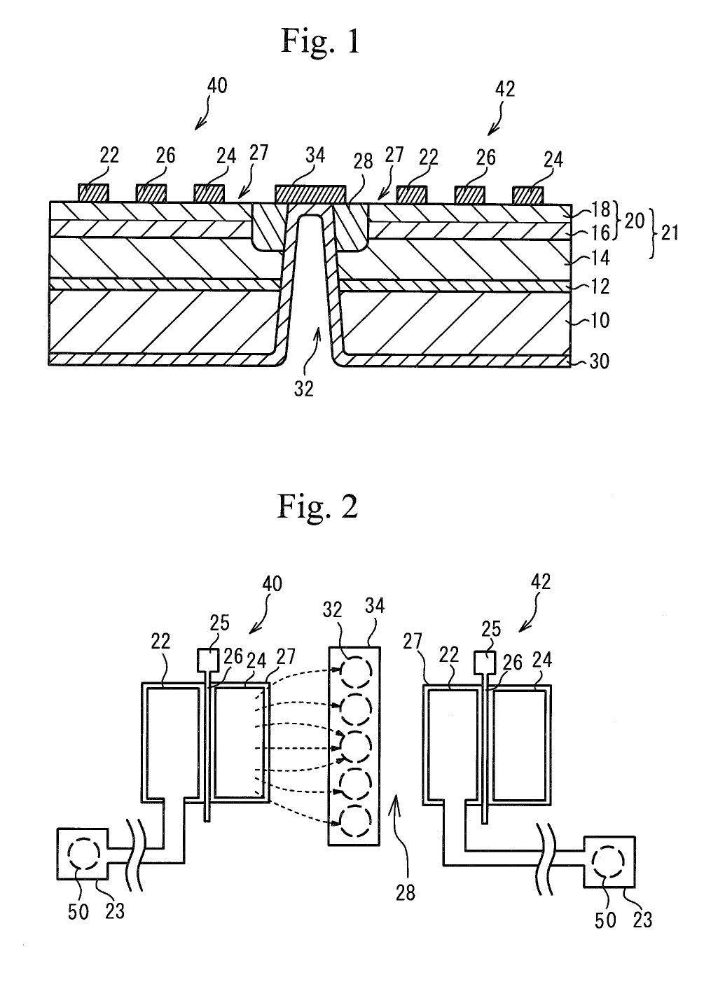

A first embodiment will now be described with reference to FIGS. 1 and 2. FIG. 1 is a schematic cross-sectional view of a semiconductor device in accordance with the first embodiment, and FIG. 2 is a schematic plan view thereof. Referring to FIG. 1, a p-type AlGaAs (aluminum gallium arsenide) layer 12 (p-type semiconductor layer) doped with Mg (magnesium) is provided on a GaAs (gallium arsenide) semi-insulating substrate 10 having a thickness of approximately 75 μm. The p-type AlGaAs layer 12 has a doping concentration of 2×10¹⁷ cm⁻³, and a thickness of approximately 10 nm. An undoped buffer layer 14 having a thickness of approximately 600 nm is provided on the p-type AlGaAs layer 12. The buffer layer 14 may be a GaAs layer or an AlGaAs layer. An InGaAs (indium gallium arsenide) channel layer 16 is provided on the buffer layer 14. An n-type AlGaAs electron supply layer 18 doped with Si is provided on the channel layer 16. The channel layer 16 and the electron supply layer 18 form an active layer 20 in which carriers such as electrons travel. The buffer layer 14, the channel layer 16 and the electron supply layer 18 form a compound semiconductor layer 21 provided on the p-type semiconductor layer 12.

As shown in FIGS. 1 and 2, source electrodes 22, drain electrodes 24 and gate electrodes 26 are provided on the electron supply layer 18. The source electrodes 22 and the drain electrodes 24 are ohmic electrodes. Gate pads 25 are used to connect the gate electrodes 26 to interconnection layers (not shown for the sake of simplicity). Sets of source electrodes 22, gate electrodes 26 and drain electrodes 24 form first and second FETs 40 and 42. The active layer 20 has a portion that is located around the first and second FETs 40 and 42 and is inactivated by an isolation region 28. Thus, a plurality of active regions 27 adjacent to each other across the isolation region 28 are formed in the compound semiconductor layer 21, and the first and second FETs 40 and 42 are formed in the respective active regions 27. With the above structure, the active layers 20 of the first and second FETs 40 and 42 are electrically isolated from each other by the isolation region 28.

The isolation region 28 is a B (boron) implanted region. Via holes 32 (connecting portions) having sidewalls covered with a backside metal layer 30 are formed in the isolation region 28 between the adjacent active regions 27. As shown in FIG. 2, the source electrodes 22 of the first and second FETs 40 and 42 are electrically connected to the via holes 50 provided in a region other than the active regions 27 in which the first and second FETs 40 and 42 are formed (that is, the isolation region 28). The source electrodes 22 are electrically connected to the backside metal layer 30 by the via holes 50. The pads 34 and 23 receive the via holes 32 and 50, respectively. The source electrodes 22 of the first and second FETS 40 and 42 are connected to the potential of the via holes 32 in a region other than the active regions 27. That is, the source electrodes 22 are connected to the via holes 32 via the via holes 50 and the backside metal layer 30 in a region other than the active regions 27. The source electrodes 22 may not be connected to the via holes 32 via the via holes 50 and the backside metal layer 30. For example, the source electrodes 22 may be connected to the via holes 32 via an interconnection line formed in the compound semiconductor layer 21 and the pad 34.

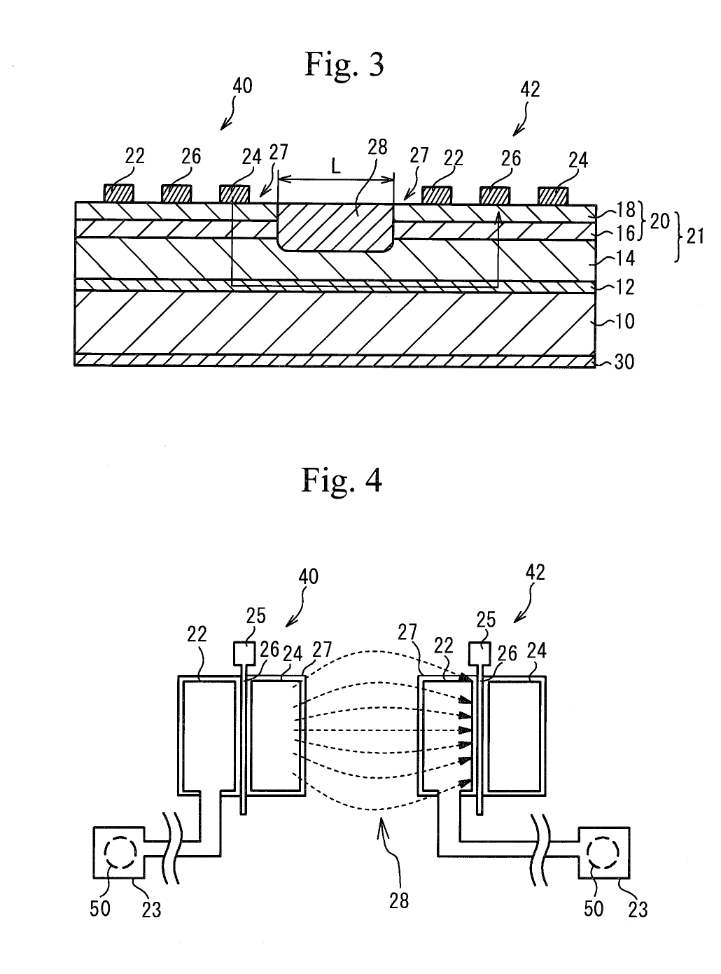

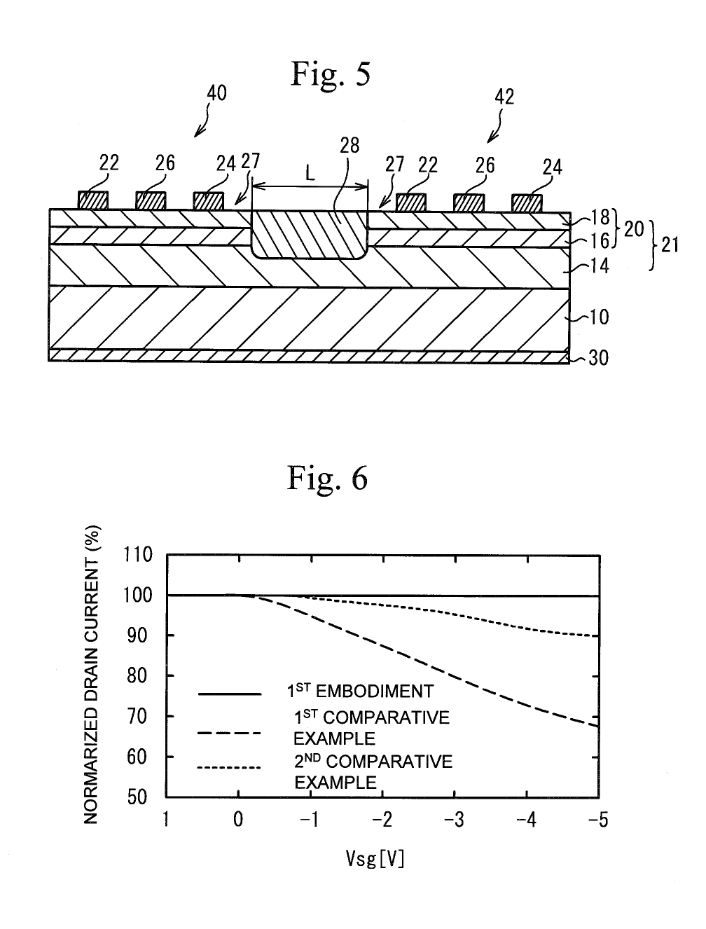

FIG. 3 is a schematic cross-sectional view of a first comparative example. FIG. 4 is a schematic plan view of first and second comparative examples. The first comparative example has a structure obtained by removing the via holes 32 and 34 from the first embodiment. FIG. 5 is a schematic cross-sectional view of the second comparative example. The second comparative example has a structure obtained by removing the p-type AlGaAs layer 12 from the first comparative example so that the buffer layer 14 is directly provided on the substrate 10. The first comparative example is equipped with the p-type AlGaAs layer 12 and is thus capable of restraining leakage current via the interface between the substrate 10 and the buffer layer 14 and improving the pinch-off characteristic, as compared to the second comparative example.

In the first and second comparative examples, the drain current of the second FET 42 was measured by applying a side-gate voltage Vsg to the drain electrode 24 of the first FET 40 for a width L of 25 μm where L is the width of the isolation region 28 between the first FET 40 and the second FET 42. FIG. 6 is a graph of normalized drain current vs. the side-gate voltage Vsg characteristics of the first and second comparative examples. The normalized drain current is defined by normalizing the drain current by the specific drain current for Vsg of 0 V. That is, the second FET 42 is an FET that receives the side-gate effect, and the drain electrode of the first FET 40 is used to receive the side-gate voltage. The graph of FIG. 6 shows that the side-gate effect of the first comparative example is greater than that of the second comparative example. This may be analyzed so that, as indicated by arrows in FIGS. 3 and 4, the side-gate voltage applied to the drain electrode 24 of the first FET 40 via the p-type AlGaAs layer 12 affects the channel layer 16 under the gate electrode 26 of the second FET 42 and increases the side-gate effect.

A solid line shown in FIG. 6 is a characteristic obtained by simulating the side-gate effect in the first embodiment. In the simulation, it is assumed that the p-type AlGaAs layer 12 under the isolation region 28 between the first FET 40 and the second FET 42 is fixed at the same potential as that of the source electrode 22 of the second FET 42. The first embodiment hardly has the side-gate effect. Since the p-type AlGaAs layer 12 is fixed at the same potential as that of the source electrode 22 of the second FET 42, as indicated by the arrows in FIG. 2, the side-gate voltage does not affect the second FET 42 via the p-type AlGaAs layer 12. It is thus possible to restrain the side-gate effect.

In the above description, the via holes 32 having the sidewalls covered with the backside metal layer 30 function as connecting portions. The connecting portions are required to be connected to the p-type AlGaAs layer 12 in the isolation region 28 and connect this layer 12 to the source electrode 22 of the second FET 42. That is, the connecting portions are required to set the p-type AlGaAs layer 12 in the isolation region 28 at a potential equal to that of the source electrode 22 of the second FET 42. Thus, the connecting portions are not limited to the connections with the p-type AlGaAs layer 12 made from the side of the substrate 10 but may include connections made from the side of the compound semiconductor layer 21. The side-gate effect can be restrained by setting the source electrode 22 to the potential of the connecting portions for making connections with the p-type AlGaAs layer 12.

In the first embodiment, it is essential to electrically connect the source electrode 22 of at least the second FET 42 affected by the side-gate effect to the via holes 32. In other words, in the first embodiment, it is essential to connect the source electrode 22 of the second FET 42 to the potential of the via holes 32 (that is, the potential of the p-type AlGaAs layer 12). Preferably, the potential of the via holes is the ground potential.

The FET described in the aforementioned application publication has the source electrode connected to the backside metal layer by a via hole within the active region. It is thus possible to radiate heat generated by the FET to the backside metal layer using the via hole. It is further possible to reduce the inductance between the source electrode and the backside metal layer. In contrast, when heat generated by the FET or the inductance between the source electrode and the backside metal layer is not relatively important, the connection of the source electrode with the backside metal layer within the active region increases the chip area. The first embodiment avoids this problem because the source electrodes 22 are connected to the backside metal layer 30 in the region other than the active region 27 via the via holes 50 and may have a reduced chip area.

In the above description, the side-gate voltage is applied to the drain electrode 24 of the first FET 40. The side-gate voltage may be applied to an electrode provided on the active layer 20 electrically separated from the active layer 20 of the second FET 42. A side-gate effect similar to that shown in FIG. 6 may take place in another arrangement in which the first FETs 40 of the first and second comparative examples are replaced by only the drain electrodes 24 formed on the active layer 20. In contrast, the side-gate effect can be restrained in a variation of the first embodiment in which the first FET 40 is replaced by only the drain electrode 24 on the active layer 20.

The side-gate effect can be restrained even when another semiconductor layer is provided between the p-type AlGaAs layer 12 and the substrate 10. However, it is preferable that the p-type AlGaAs layer 12 is provided in contact with the substrate 10. It is thus possible to restrain the leakage current flowing through the interface between the substrate 10 and the semiconductor layer provided thereon.

The p-type semiconductor layer of the above-mentioned first embodiment is the p-type AlGaAs layer 12. Essentially, the p-type semiconductor layer is a compound semiconductor layer such as a GaAs layer. Preferably, the p-type semiconductor layer has a band gap greater than the band gaps of the channel layers 16 of the first and second FETs 40 and 42. It is thus possible to further improve the pinch-off characteristics of the first and second FETS 40 and 42.

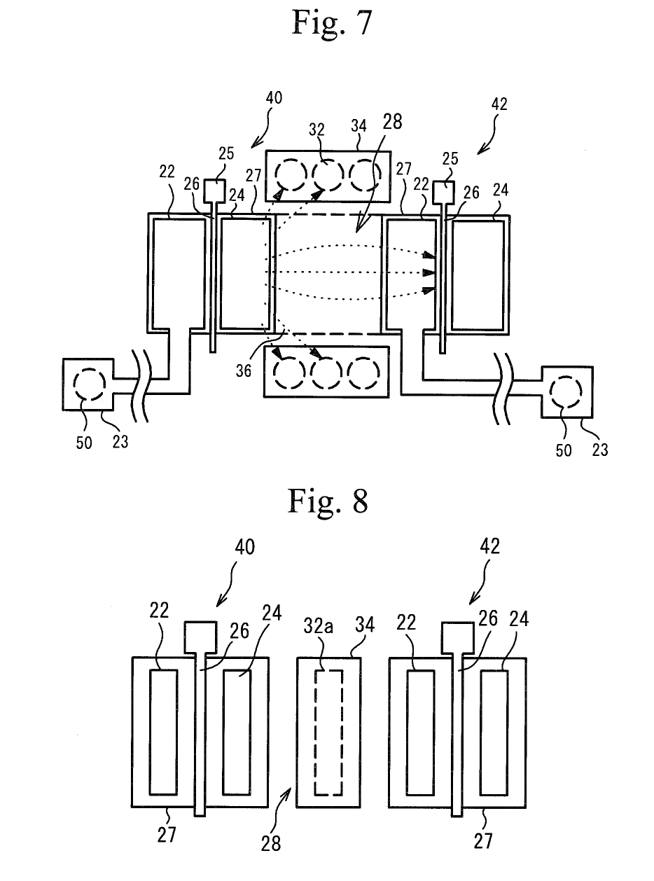

As shown in FIG. 7, the via holes 32 may be provided at both sides of a region 36 interposed between the first FET 40 and the second FET 42. Even in this arrangement, part of the affect to the second FET 42 caused by the side-gate voltage may be restrained by the via holes 32 as indicated by arrows shown in FIG. 7. As described above, the via holes 32 are required to be connected to the p-type AlGaAs layer 12 in the isolation region 28 located between the active regions 27 shown in FIG. 2 or adjacent to the region 36 between the active regions 27 shown in FIG. 7. Preferably, the via holes 32 are provided between the first FET 40 (in other words, the electrode to which the side-gate voltage is applied) and the FET 42. Only one via hole 32 may be used instead of the multiple via holes 32 shown in FIG. 2.

The via holes 32 may be connected to the source electrode 22 of the second FET 42 outside of the semiconductor device. The via holes 32 may be connected to the source electrode 22 of the second FET 42 within the semiconductor device, as shown in FIG. 2. The isolation region 28 is not limited to the inactive region defined by ion implantation but may be a mesa structure defined by etching.

### Second Embodiment

A second embodiment and its variations will now be described with reference to FIGS. 8 through 10. As shown in FIG. 8, a via hole 32a is continuously provided between the first FET 40 and the second FET 42. The other structure of the second embodiment is the same as that of the first embodiment.

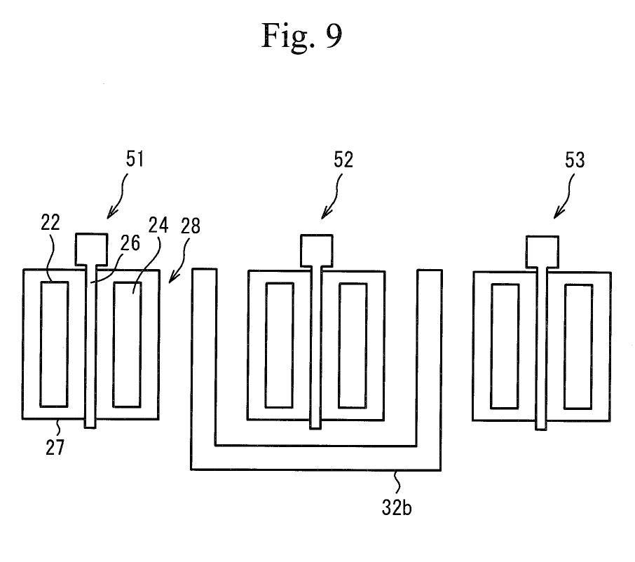

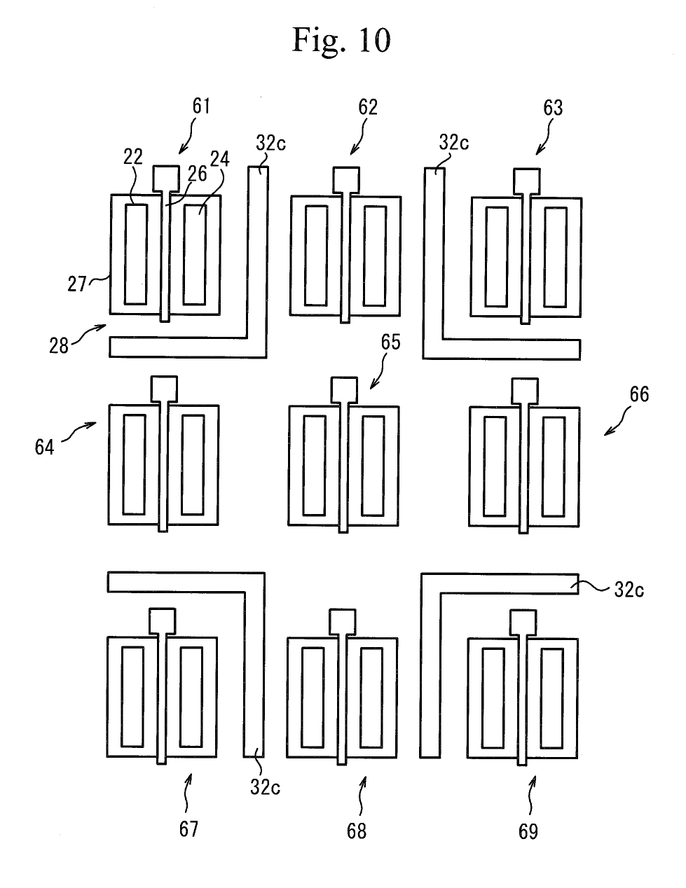

A first variation of the second embodiment shown in FIG. 9 has FETs 51 through 53. A via hole 32b has a C shape with respect to the surface of the substrate 10 in which the C shape has a portion located between the FETs 51 and 52, and another portion between the FETs 52 and 53. A second variation of the second embodiment shown in FIG. 10 has FETs 61 through 69. Via holes 32c are formed into an L shape with respect to the surface of the substrate 10. For example, one of the via holes 32c is provided between the FETs 61 and 62 and between the FETs 61 and 64. The other via holes 32c are similarly provided around the FETs 63, 67 and 69. In FIGS. 9 and 10, pads for the via holes 32b and 32c are not illustrated for the sake of simplicity.

As shown in FIGS. 8 through 10, when the voltage applied to an FET is negative with respect to the voltage applied to an adjacent FET, the via holes 32a through 32c are preferably provided continuously between these FETs (that is, the electrode to which the side-gate voltage is applied and the second FET 42). It is thus possible to further restrain the side-gate effect. For example, the arrangement shown in FIG. 10 is capable of restraining the side-gate effect in a case where the FETs 61, 63, 67 and 69 have potentials negative to those of the FETs 62, 64, 65, 66 and 68.

In the first and second embodiments and their variations, the multiple adjacent active regions 27 are provided via the isolation regions 28, and the multiple FETs are provided in the respective adjacent active regions 27. The source electrode 22 of at least one of the FETs (which receives the side-gate effect) is connected to the potential of the via holes 32 connected to the p-type AlGaAs layer 12 in the region other than the active regions 27. It is thus possible to restrain the side-gate effect.

### Third Embodiment

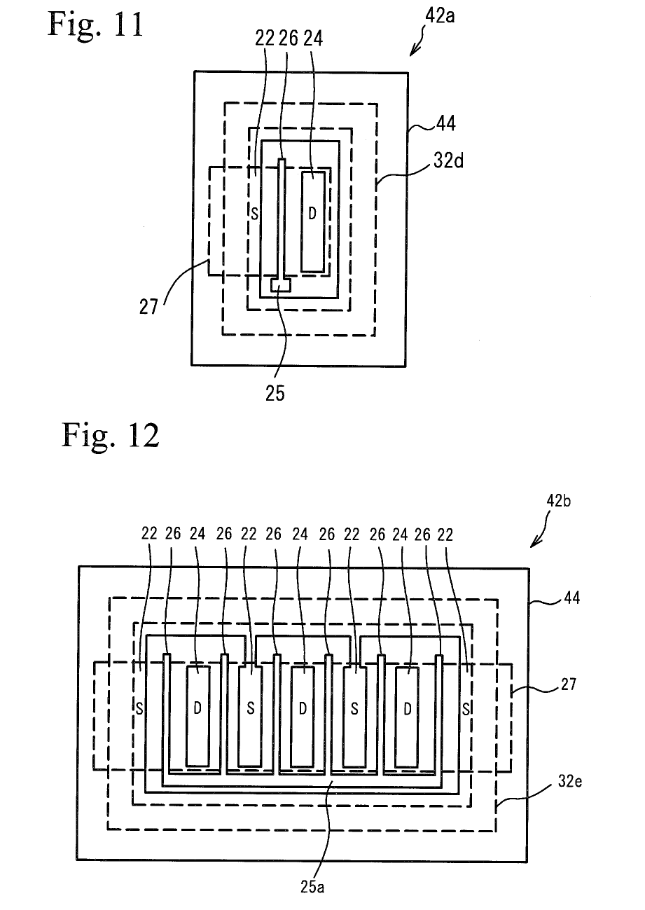

A third embodiment and its variation will now be described with reference to FIGS. 11 and 12. The third embodiment shown in FIG. 11 has an arrangement in which the source electrode 22 of an FET 42a and a pad 44 of the via hole 32d are integrated, and the via hole 32d surrounds the periphery of the FET 42a. An interconnection layer (not shown) is connected to the gate pad 25 and the drain electrode 24.

A variation of the third embodiment shown in FIG. 12 is an FET having a multi-finger structure. Multiple groups are successively provided in which each of the groups has the source electrode 22, the gate electrode 26, the drain electrode 24 and the gate electrode 26 arranged in this order. The gate electrodes 26 are connected to a gate pad 25a, which is connected to an interconnection layer (not shown). The drain electrodes 24 are connected to respective interconnection layers (not shown). The source electrodes 22 are connected to the pad 44 and are thus integrated. A via hole 32e is provided so as to surround the periphery of the FET 42b.

As shown in FIGS. 11 and 12, preferably, the via holes 32d and 32e are provided so as to surround the peripheries of the FETs 42a and 42b that receive the side-gate effect. It is thus possible to further restrain the side-gate effect. In the third embodiment and the variation thereof, the pad 44 for the via hole 32d or 32e is integrally formed with the source electrodes 22. The pad 44 is not limited to the above arrangement but may be provided separate from the source electrodes 22. The via hole 32d or 32e may be varied so as to surround the periphery of the electrode to which the side-gate voltage is applied. That is, the via hole may be provided so as to surround the periphery of at least one of the FET receiving the side-gate effect and the electrode to which the side-gate voltage is applied.

The first and second embodiments may be varied so as to employ an FET having a multi-finger structure as in the case of the variation of the third embodiment.

The FETs 40, 42, 42a and 42b of the first through third embodiments are exemplary HEMTs each having the channel layer 16 and the electron supply layer 18. The present invention is not limited to the HEMTs but may be MES (Metal Semiconductor) FET.

The substrate 10 is not limited to the GaAs substrate but may be made of SiC, sapphire or GaN. The semiconductor layer is not limited to GaAs, AlGaAs or InGaAs but may be a compound semiconductor layer of GaN, AlGaN, InGaN or InGaP.

The present invention is not limited to the specifically disclosed embodiments and variations, but may include other embodiments and variations without departing from the scope of the present invention.

The present application is based on Japanese Patent Application No. 2007-016129 filed Jan. 26, 2007, the entire disclosure of which is hereby incorporated by reference.

What is claimed is:

1. A semiconductor device comprising:
a p-type semiconductor layer made of a compound semiconductor provided on a substrate;
a compound semiconductor layer provided on the p-type semiconductor layer;
active regions that are provided on the compound semiconductor layer and are adjacent to each other across an isolation region;
a connecting portion that is connected to the p-type semiconductor layer in the isolation region located between the active regions or a region adjacent to another region between the active regions; and
FETs respectively provided in the active regions adjacent to each other, a source electrode of at least one of the FETs being connected to a potential of the connecting portion in a region other than the active regions.

2. The semiconductor device as claimed in claim 1, wherein the potential of the connecting portion is a ground potential.

3. The semiconductor device as claimed in claim 1, wherein the p-type semiconductor layer is provided in contact with the substrate.

4. The semiconductor device as claimed in claim 1, wherein the isolation region is an ion-implanted region.

5. The semiconductor device as claimed in claim 1, wherein the connecting portion is a via hole connected to the substrate.

6. The semiconductor device as claimed in claim 1, wherein the connecting portion is provided so as to surround the FETs.

7. The semiconductor device as claimed in claim 1, wherein the connecting portion is connected to source electrodes of the FETs.

8. The semiconductor device as claimed in claim 1, wherein the connecting portion has one of an L shape and a C shape with respect to a surface of the substrate.

9. The semiconductor device as claimed in claim 1, wherein the FETs are MESFET or HEMT.

10. The semiconductor device as claimed in claim 1, wherein the substrate is made of one of GaAs, SiC, sapphire and GaN.
